(19) United States
(12) Patent Application Publication
(10) Pub. No.: US 2019/0037696 A1
(43) Pub. Date: Jan. 31, 2019

(54) MULTILAYER CAPACITOR BUILT-IN SUBSTRATE

(71) Applicant: Murata Manufacturing Co., Ltd., Nagaokakyo-shi (JP)

(72) Inventors: Tadateru YAMADA, Nagaokakyo-shi (JP); Masaru TAKAHASHI, Nagaokakyo-shi (JP); Isamu FUJIMOTO, Nagaokakyo-shi (JP); Kazuo HATTORI, Nagaokakyo-shi (JP)

(21) Appl. No.: 16/134,061

(22) Filed: Sep. 18, 2018

Related U.S. Application Data
(63) Continuation of application No. PCT/JP2017/008248, filed on Mar. 2, 2017.

(30) Foreign Application Priority Data
Mar. 18, 2016 (JP) 2016-055588

(51) Int. Cl. H05K 1/16; H01G 4/30; H01G 4/12

(52) U.S. Cl. CPC H05K 1/162; H01G 4/12; H01G 4/30

(57) ABSTRACT

A multilayer capacitor built-in substrate includes a circuit board, a multilayer capacitor mounted on one principal surface of the circuit board, a first resin layer provided on the one principal surface of the circuit board, and a second resin layer provided on the first resin layer and embedding the multilayer capacitor. The Young's modulus of the first resin layer is smaller than that of the second resin layer.

### CROSS REFERENCE TO RELATED APPLICATIONS

This application claims the benefit of priority to Japanese Patent Application No. 2016-055588 filed on Mar. 18, 2016 and is a Continuation Application of PCT Application No. PCT/JP2017/008248 filed on Mar. 2, 2017. The entire contents of each application are hereby incorporated herein by reference.

### BACKGROUND OF THE INVENTION

### 1. Field of the Invention

The present invention relates to a multilayer capacitor built-in substrate.

### 2. Description of the Related Art

The capacitance of multilayer ceramic capacitors as electronic components has been increased with recent improvements of the performance of electronic devices. In a large-capacitance multilayer ceramic capacitor, a high-dielectric-constant ceramic material, such as barium titanate, is used as a dielectric material.

Such a high-dielectric-constant ceramic material has piezoelectric and electrostrictive properties, and thus, when voltage is applied, mechanical distortion occurs in a multilayer ceramic capacitor including a dielectric made of a high-dielectric-constant ceramic material.

Thus, when alternating-current voltage or direct-current voltage with an alternating-current component superimposed thereon is applied to the multilayer ceramic capacitor mounted on a circuit board, vibration attributable to distortion of the multilayer ceramic capacitor is generated at the multilayer ceramic capacitor. This vibration propagates to the circuit board, and accordingly, the circuit board vibrates.

When the circuit board vibrates at a frequency in the audible frequency range of 20 Hz to 20,000 Hz inclusive due to the propagating vibration, noise called “acoustic noise” is generated.

Various kinds of technologies have been disclosed to reduce the above-described noise. For example, Japanese Patent Application Laid-open No. 2000-232030 discloses a mounting structural body in which multilayer ceramic capacitors to which equivalent voltages are applied are each mounted at plane-symmetrical positions on the front and back surfaces of the circuit board. According to Japanese Patent Application Laid-open No. 2000-232030, noise reduction is able to be achieved by causing vibration propagating from one of the multilayer ceramic capacitors to the circuit board and vibration propagating from the other multilayer ceramic capacitor to the circuit board to cancel each other.

However, the technology disclosed in Japanese Patent Application Laid-open No. 2000-232030 is applicable only when multilayer ceramic capacitors are able to be mounted on both surfaces of the circuit board, but is not applicable when a multilayer ceramic capacitor is able to be mounted on only one surface of the circuit board. This decreases the freedom of design.

### SUMMARY OF THE INVENTION

Preferred embodiments of the present invention provide multilayer capacitor built-in substrates that are each able to reduce vibration of the entire multilayer capacitor built-in substrate so that noise from a circuit board is reduced without decreasing design freedom.

A multilayer capacitor built-in substrate according to a preferred embodiment of the present invention includes a circuit board, a multilayer capacitor mounted on one principal surface of the circuit board, a first resin layer provided on the one principal surface of the circuit board, and a second resin layer provided on the first resin layer and embedding the multilayer capacitor. The Young's modulus of the first resin layer is smaller than that of the second resin layer.

In a multilayer capacitor built-in substrate according to a preferred embodiment of the present invention, the circuit board is completely covered by the first resin layer and the second resin layer, and thus, vibration attributable to distortion of the multilayer capacitor propagates not only to the circuit board but also to the first resin layer and the second resin layer. Accordingly, vibration propagating toward the circuit board and vibration propagating toward the resin layer cancel each other. Moreover, since the first resin layer is provided between the circuit board and the second resin layer, vibration is absorbed by the first resin layer having the smaller Young's modulus. For these reasons, vibration of the entire multilayer capacitor built-in substrate is able to be reduced, and thus, noise from the circuit board is reduced.

In a multilayer capacitor built-in substrate according to a preferred embodiment of the present invention, it is preferable that the first resin layer is also provided on an upper surface and a side surface of the multilayer capacitor to cover the multilayer capacitor.

When the first resin layer having the lower Young's modulus is provided on the upper surface and the side surface of the multilayer capacitor, vibration attributable to distortion of the multilayer capacitor is absorbed by the first resin layer, thus further reducing vibration of the entire multilayer capacitor built-in substrate.

In a multilayer capacitor built-in substrate according to a preferred embodiment of the present invention, it is preferable that E1/E2<about 0.5 is satisfied where the Young's modulus of the first resin layer is represented by E1 [GPa] and the Young's modulus of the second resin layer is represented by E2 [GPa].

The Young's modulus difference between the first resin layer and the second resin layer is able to be increased by setting the ratio of the Young's modulus E1 of the first resin layer relative to the Young's modulus E2 of the second resin layer to be in the above-described range, thus further reducing vibration of the entire multilayer capacitor built-in substrate.

In a multilayer capacitor built-in substrate according to a preferred embodiment of the present invention, it is preferable that the thickness of the first resin layer is smaller than the thickness of the multilayer capacitor.

In a multilayer capacitor built-in substrate according to a preferred embodiment of the present invention, it is preferable that the first resin layer and the second resin layer each include epoxy resin.

Preferred embodiments of the present invention provide multilayer capacitor built-in substrates that are each able to reduce vibration of the entire multilayer capacitor built-in substrate so that noise from a circuit board is reduced without decreasing design freedom.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view schematically illustrating a multilayer capacitor built-in substrate according to a preferred embodiment of the present invention.

FIG. 2 is a cross-sectional view schematically illustrating a multilayer capacitor built-in substrate according to another preferred embodiment of the present invention.

FIG. 3 is a table listing the configurations of multilayer capacitor built-in substrates in examples and comparative examples.

FIG. 4 illustrates a simulation result indicating the amounts of vibration of the multilayer capacitor built-in substrates in the examples and the comparative examples.

### DETAILED DESCRIPTION OF THE PREFERRED EMBODIMENTS

Multilayer capacitor built-in substrates according to preferred embodiments of the present invention will be described below with reference to the drawings.

The present invention is not limited to configurations described below, but may be modified as appropriate without departing from the scope of the present invention.

Preferred embodiments of the present invention also include a combination of two or more individual preferable configurations according to the present invention described below.

Although each preferred embodiment below describes an example in which the multilayer capacitor is a multilayer ceramic capacitor, the multilayer capacitor is not limited to a ceramic material and may be made of any dielectric material to which distortion occurs by voltage application. Preferred embodiments of the present invention are also applicable to, for example, a multilayer metalized film capacitor that is a multilayer capacitor made of a resin material as a dielectric material other than a ceramic material.

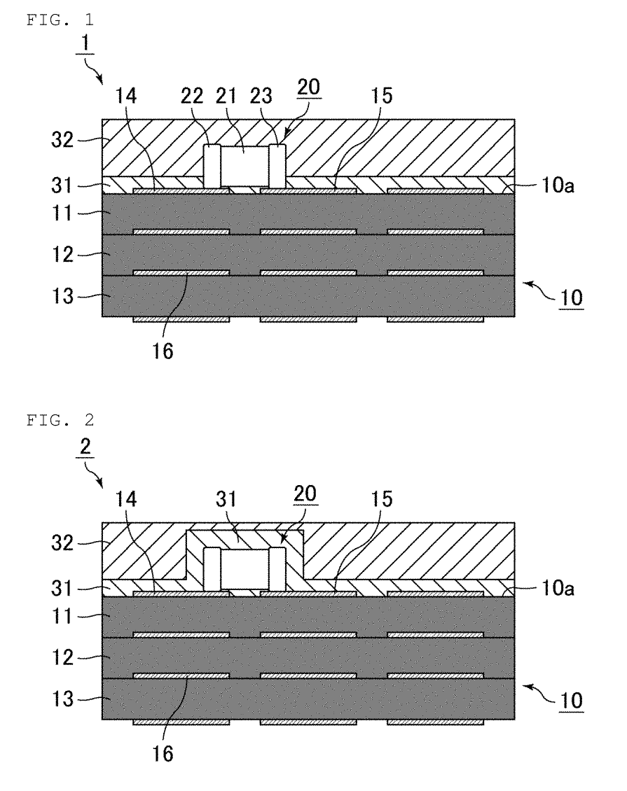

FIG. 1 is a cross-sectional view schematically illustrating a multilayer capacitor built-in substrate according to a preferred embodiment of the present invention.

The multilayer capacitor built-in substrate 1 illustrated in FIG. 1 includes a circuit board 10, a multilayer ceramic capacitor 20, a first resin layer 31, and a second resin layer 32. Although not illustrated in FIG. 1, a conductive portion may be further provided on the surface of the second resin layer 32.

The multilayer ceramic capacitor 20 is mounted on one principal surface 10a of the circuit board 10. The first resin layer 31 is provided on the one principal surface 10a of the circuit board 10. The second resin layer 32 is provided on the first resin layer 31 and embeds the multilayer ceramic capacitor 20.

In FIG. 1, the multilayer ceramic capacitor 20 preferably has a rectangular or substantially rectangular parallelepiped shape as a whole, and includes an element body 21 and a pair of external electrodes 22 and 23.

The element body included in the multilayer ceramic capacitor preferably has a rectangular or substantially rectangular parallelepiped shape and includes a dielectric layer and an internal electrode layer alternately laminated in a predetermined direction. The dielectric layer is preferably made of, for example, a ceramic material including barium titanate (BaTiO₃) as a main component. The internal electrode layer is preferably made of, for example, a metallic material such as Ni, Cu, Ag, Pd, an Ag—Pd alloy, or Au.

The element body is produced by preparing a plurality of material sheets in each of which conductive paste as the internal electrode layer is printed on the surface of a ceramic sheet (green sheet) as the dielectric layer, and laminating, pressure bonding, and firing the plurality of material sheets.

The material of the dielectric layer is not limited to the ceramic material including barium titanate as a main component, but may be any other high-dielectric-constant ceramic material (including, for example, CaTiO₃, SrTiO₃, or CaZrO₃ as a main component). The material of the internal electrode layer is not limited to the above-described metallic material, but may be any other conductive material.

The external electrodes included in the multilayer ceramic capacitor cover both end portions of the element body and are separated from each other. Each external electrode is preferably made of a conductive film.

Each external electrode is preferably made of a multilayer film including, for example, a sintered metal layer and a plating layer. The sintered metal layer is preferably, formed by, for example, baking paste, such as Cu, Ni, Ag, Pd, an Ag—Pd alloy, or Au. The plating layer preferably includes, for example, a Ni plating layer, and a Sn plating layer covering the Ni plating layer. Alternatively, the plating layer may be a Cu plated layer or an Au plating layer. The external electrode may only include the plating layer.

Each external electrode may be formed using conductive resin paste. When the conductive resin paste is used, a resin component included in the conductive resin paste absorbs vibration generated in the element body so that vibration propagating externally from the element body is able to be effectively attenuated, which is advantageous for noise reduction.

In FIG. 1, the circuit board 10 preferably has a flat plate shape as a whole, and includes a plurality of insulating layers 11, 12, and 13.

The circuit board 10 further includes the lands 14 and 15 defined by conductive patterns and the wire conductor 16. The lands 14 and 15 are provided on the surface of the insulating layer 11, and the multilayer ceramic capacitor 20 is mounted on the lands 14 and 15 on the insulating layer 11. Voltage is applied to the multilayer ceramic capacitor 20 through a conductive pattern of the circuit board 10.

The material of each insulating layer included in the circuit board may preferably be, for example, a resin material such as epoxy resin or polyimide resin, a ceramic material such as alumina, or a material obtained by adding, to these materials, a filler made of an inorganic material or an organic material. The insulating layer preferably includes a resin material such as thermosetting resin, and more preferably includes glass epoxy resin impregnated with epoxy resin in glass woven fabric.

The Young's modulus of each insulating layer included in the circuit board is not particularly limited, but is preferably between, for example, about 15 GPa and about 30 GPa inclusive.

The Young's modulus of the insulating layer may be calculated by the same method as that for the Young's modulus of a resin layer such as the first resin layer to be described later.

The thickness of each insulating layer included in the circuit board is not particularly limited, but is preferably, for example, about 15 μm or larger and about 1000 μm or smaller to reduce vibration.

The circuit board may be formed by, for example, a lump layering method or a build-up method. When the circuit board is formed by the lump layering method, first, a plurality of insulating layers on each of which a conductive pattern is formed is prepared. Then, the insulating layers are laminated and pressure bonded, and then, the resin material is thermally cured or the ceramic material is fired to form the circuit board. When the circuit board is formed by the build-up method, first, a support substrate, such as a glass epoxy resin substrate, is prepared, and conductive layers are formed on both surfaces of the support substrate with bonding layers of prepreg interposed therebetween. Then, formation of a conductive pattern by patterning of the conductive layer using photolithography and a resist film and lamination of an insulating layer are repeated to form the circuit board.

In FIG. 1, the lands 14 and 15 are positioned separately from each other on the one principal surface 10a of the circuit board 10 on which the multilayer ceramic capacitor 20 is mounted. The lands 14 and 15 correspond to portions of a conductive pattern, and are arranged on the insulating layer 11 for the external electrodes 22 and 23 of the multilayer ceramic capacitor 20. Various conductive materials may be used as the material of the lands 14 and 15, and typically, a metallic material, such as copper foil, for example, is preferably used.

The external electrode 22 of the multilayer ceramic capacitor 20 and the land 14 provided to the circuit board 10 are bonded to each other through a conductive bonding member. Similarly, the external electrode 23 of the multilayer ceramic capacitor 20 and the land 15 provided to the circuit board 10 are bonded to each other through a conductive bonding member. These bonding members may preferably be, for example, a conductive adhesive or solder. When a conductive adhesive is used as the bonding members, a resin component included in the conductive adhesive absorbs vibration generated at the multilayer ceramic capacitor so that vibration propagating from the multilayer ceramic capacitor to the outside is able to be effectively attenuated, which is advantageous for noise reduction.

In FIG. 1, the first resin layer 31 is provided entirely or substantially entirely on the one principal surface 10a of the circuit board 10 on which the multilayer ceramic capacitor 20 is mounted.

In this manner, in a multilayer capacitor built-in substrate according to a preferred embodiment of the present invention, the first resin layer is preferably provided entirely or substantially entirely on the principal surface of the circuit board on which the multilayer ceramic capacitor is mounted. In other words, the principal surface of the circuit board on which the multilayer ceramic capacitor is mounted is preferably covered by the first resin layer.

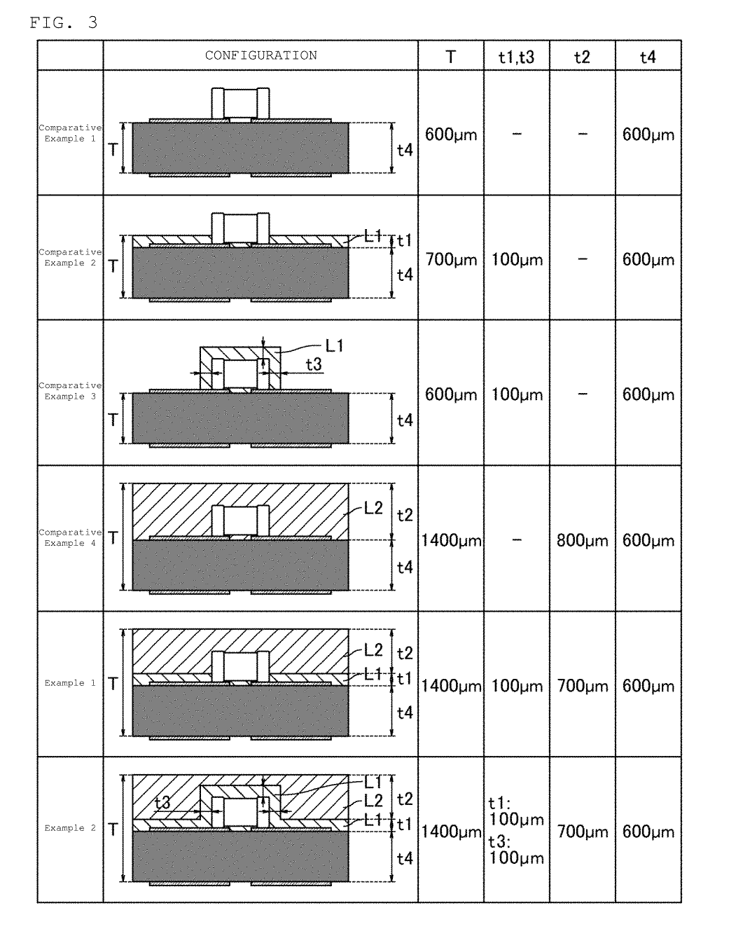

FIG. 2 is a cross-sectional view schematically illustrating a multilayer capacitor built-in substrate according to another preferred embodiment of the present invention.

In the multilayer capacitor built-in substrate 2 illustrated in FIG. 2, the first resin layer 31 is also provided on an upper surface and a side surface of the multilayer ceramic capacitor 20 to cover the multilayer ceramic capacitor 20.

In multilayer capacitor built-in substrates according to preferred embodiments of the present invention, the first resin layer only needs to be in contact with a portion of the multilayer ceramic capacitor as illustrated in FIG. 1, but is preferably also provided on the upper surface and side surface of the multilayer ceramic capacitor, more preferably provided entirely or substantially entirely on the upper surface and side surface of the multilayer ceramic capacitor, to cover the multilayer ceramic capacitor as illustrated in FIG. 2.

The Young's modulus of the first resin layer is smaller than that of the second resin layer.

The Young's modulus of the first resin layer is not particularly limited as long as it is smaller than that of the second resin layer, but is preferably smaller than about 10 GPa, and more preferably smaller than about 3 GPa, for example, to prevent vibration. The Young's modulus of the first resin layer is preferably about 0.01 GPa or larger, and more preferably about 0.05 GPa or larger, for example.

The Young's modulus of a resin layer such as the first resin layer may be calculated using a test piece having a width of about 25 mm and a length of about 150 mm according to JIS K 7161.

The material of the first resin layer may preferably be, for example, a resin material such as epoxy resin, polyimide resin, or urethane resin, or a material obtained by adding, to these resin materials, a filler made of an inorganic material or an organic material. The first resin layer preferably includes a thermosetting resin material, and more preferably includes epoxy resin.

The Young's modulus of a resin layer such as the first resin layer is able to be controlled according to, for example, the included amount of a filler made of glass or silica. Specifically, the Young's modulus is able to be increased by increasing the included amount of the filler. The Young's modulus of a resin layer such as the first resin layer is also able to be controlled by changing the kind of resin material.

When the Young's modulus of the first resin layer is represented by E1 [GPa] and the Young's modulus of the second resin layer is represented by E2 [GPa], E1/E2<about 0.5 is preferably satisfied, and E1/E2<about 0.33 is more preferably satisfied, for example, to reduce vibration.

The thickness of the first resin layer is not particularly limited, but is preferably smaller than the thickness of the multilayer ceramic capacitor, and more preferably about half or less of the thickness of the multilayer ceramic capacitor. Specifically, the thickness of the first resin layer is preferably about 300 μm or smaller, and more preferably about 200 μm or smaller, for example. The thickness of the first resin layer is preferably about 50 μm or larger, for example.

When the first resin layer is provided on the upper surface and the side surface of the multilayer ceramic capacitor, the thickness of the first resin layer on the upper surface and the side surface of the multilayer ceramic capacitor is preferably equal or substantially equal to the thickness of the first resin layer on the circuit board.

When the total thickness of the resin layers is represented by t0 [μm] and the thickness of the first resin layer is represented by t1 [μm], t1/t0 about 0.03 is preferably satisfied, and t1/t0 about 0.16 is more preferably satisfied, for example, to reduce vibration. It is also preferable that t1/t0 about 0.85 is satisfied, for example.

In FIG. 1, the second resin layer 32 directly embeds the multilayer ceramic capacitor 20. In other words, the multilayer ceramic capacitor 20 is directly covered by the second resin layer 32.

However, in multilayer capacitor built-in substrates according to preferred embodiments of the present invention, the second resin layer does not need to directly embed the multilayer ceramic capacitor, but may embed the multilayer ceramic capacitor covered by the first resin layer as illustrated in FIG. 2.

Similarly to the material of the first resin layer, the material of the second resin layer may preferably be, for example, a resin material such as epoxy resin, polyimide resin, or urethane resin, or a material obtained by adding, to these resin materials, a filler made of an inorganic material or an organic material. The second resin layer preferably includes the same or substantially the same thermosetting resin material as that of the first resin layer, and more preferably includes epoxy resin, for example. Specifically, the material of the second resin layer is preferably epoxy resin in which the included amount of a filler made of glass or silica is larger than in the first resin layer. The material of the first resin layer may be epoxy resin that does not include the above-described filler or may be epoxy resin in which the included amount of the above-described filler is smaller than in the second resin layer.

The Young's modulus of the second resin layer is not particularly limited as long as it is larger than that of the first resin layer, but is preferably about 10 GPa or larger, and more preferably 15 GPa or larger, for example. The Young's modulus of the second resin layer is also preferably about 30 GPa or smaller, and more preferably about 25 GPa or smaller, for example.

The thickness of the second resin layer only needs to be enough to embed the multilayer ceramic capacitor, and may be selected as appropriate in accordance with the thickness of the multilayer ceramic capacitor and the thickness of the first resin layer.

For example, the thickness of the second resin layer is preferably about 1 mm or smaller, and more preferably 800 μm or smaller. The thickness of the second resin layer is also preferably about 500 μm or larger, for example.

The thickness of the second resin layer is the thickness of a portion at which the multilayer ceramic capacitor is not provided, and thus, is the thickness of the second resin layer provided on the first resin layer on the circuit board.

The first resin layer and the second resin layer can be formed by, for example, a non-limiting example of a method described below. First, the circuit board on which the multilayer ceramic capacitor is mounted is prepared. In addition, first resin (for example, epoxy resin) and second resin (for example, epoxy resin with an added filler) having a Young's modulus larger than that of first resin are prepared. The first resin and the second resin are preferably liquid, and the viscosity of the second resin is preferably higher than that of the first resin. Subsequently, the first resin is applied on the principal surface of the circuit board on which the multilayer ceramic capacitor is mounted, and then cured to form the first resin layer on one principal surface of the circuit board. The first resin layer may be formed also on the upper surface and the side surface of the multilayer ceramic capacitor. Subsequently, the second resin is applied on the first resin layer to completely or almost completely cover the multilayer ceramic capacitor, and then is cured to form the second resin layer embedding the multilayer ceramic capacitor.

The first resin and the second resin may be sheets. In this case, a first resin sheet is disposed on the principal surface of the circuit board on which the multilayer ceramic capacitor is mounted, and a second resin sheet is disposed on the first resin sheet, and then these resin sheets are cured, so that the first resin layer and the second resin layer are formed.

After the second resin layer is formed, grinding processing may be performed to flatten the surface of the second resin layer.

The structures of the multilayer capacitor built-in substrates illustrated in FIGS. 1 and 2 are merely exemplary. The number of laminated resin layers, the configuration of the circuit board, and other features and characteristics may be changed in various manners as long as a first resin layer having the smaller Young's modulus is provided on one principal surface of the circuit board on which the multilayer ceramic capacitor is mounted, and a second resin layer having the larger Young's modulus is provided on the first resin layer and embeds the multilayer ceramic capacitor.

For example, the first resin layer does not need to be adjacent to the second resin layer, and a resin layer having a Young's modulus smaller than that of the first resin layer may be disposed between the first resin layer and the second resin layer. Another resin layer may be provided on the second resin layer.

Preferred embodiments of the present invention are described above, but the multilayer capacitor built-in substrate according to the present invention is not limited to the above-described preferred embodiments.

In the multilayer capacitor built-in substrates according to preferred embodiments of the present invention, when alternating-current voltage or direct-current voltage with an alternating-current component superimposed thereon is applied to the multilayer capacitors, vibration of the entire multilayer capacitor built-in substrates is reduced so that noise from the circuit board is able to be reduced. Thus, the circuit boards included in the multilayer capacitor built-in substrates according to preferred embodiments of the present invention are each preferably a substrate provided with a conductive pattern to which alternating-current voltage or direct-current voltage with an alternating-current component superimposed thereon is applied, and particularly, a substrate provided with a conductive pattern with which the voltage applied to the multilayer capacitor varies at a frequency in the audible frequency range of 20 Hz to 20,000 Hz inclusive.

Although in the above-described preferred embodiments, a configuration in which one multilayer capacitor is mounted on one principal surface of the circuit board, have been described, a plurality of multilayer capacitors may be mounted one principal surface of the circuit board in the multilayer capacitor built-in substrates according to preferred embodiments of the present invention. In addition, an electronic component other than a multilayer capacitor may be mounted on the circuit board.

The following describes examples more specifically disclosing the multilayer capacitor built-in substrates according to preferred embodiments of the present invention. The present invention is not limited to these examples.

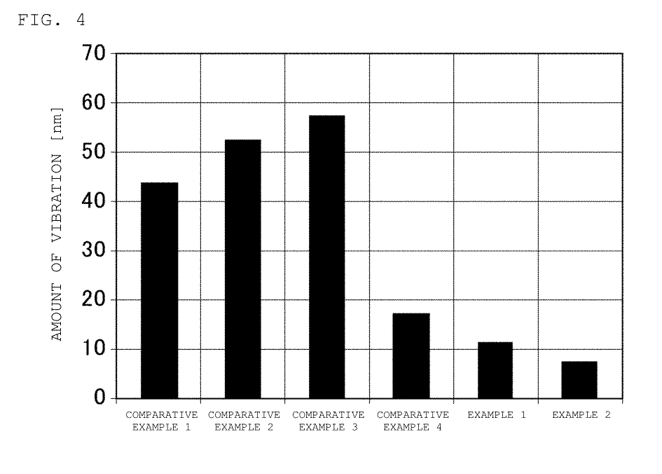

FIG. 3 is a table listing the configurations of multilayer capacitor built-in substrates in examples of preferred embodiments of the present invention and comparative examples. In each of Comparative Examples 1 to 3, the multilayer ceramic capacitor is not embedded by a resin layer, but the configuration is referred to as a multilayer capacitor built-in substrate for sake of simplicity. Each of the examples and the comparative examples used a multilayer ceramic capacitor having the 1005 size (about 1.0 mm× about 0.5 mm; the thickness: about 0.5 mm) and a capacitance of about 10 μF. The multilayer ceramic capacitor was mounted on a copper land (thickness: about 0.018 mm) on a circuit board.

The circuit board includes a glass epoxy resin layer (Young's modulus: about 25 GPa) as an insulating layer.

In the examples and the comparative examples, resin layers are configured as follows.

Comparative Example 1: no resin layer is provided on a principal surface of the circuit board.

Comparative Example 2: a first epoxy resin layer L1 (Young's modulus: about 1 GPa; the same in the other examples) is provided on a principal surface of the circuit board. The first epoxy resin layer L1 is not provided on the upper surface and the side surface of the multilayer ceramic capacitor.

Comparative Example 3: the first epoxy resin layer L1 is provided on the upper surface and the side surface of the multilayer ceramic capacitor. The first epoxy resin layer L1 is not provided on a principal surface of the circuit board.

Comparative Example 4: a second epoxy resin layer L2 (Young's modulus: about 15 GPa; the same in the other examples) embedding the multilayer ceramic capacitor is provided on a principal surface of the circuit board.

Example 1: the first epoxy resin layer L1 is provided on a principal surface of the circuit board, and the second epoxy resin layer L2 embedding the multilayer ceramic capacitor is provided on the first epoxy resin layer L1. The first epoxy resin layer L1 is not provided on the upper surface and the side surface of the multilayer ceramic capacitor.

Example 2: the first epoxy resin layer L1 is provided on the principal surface of the circuit board and also on the upper surface and the side surface of the multilayer ceramic capacitor, and the second epoxy resin layer L2 embedding the multilayer ceramic capacitor is provided on the first epoxy resin layer L1.

FIG. 3 lists thicknesses t1 and t3 of the first epoxy resin layer L1, a thickness t2 of the second epoxy resin layer L2, a thickness t4 of the glass epoxy resin layer as an insulating layer of the circuit board, and a total thickness T of the glass epoxy resin layer, the first epoxy resin layer L1, and the second epoxy resin layer L2.

Vibration analysis by a finite element method was performed on the multilayer capacitor built-in substrate in each of the examples and the comparative examples.

FIG. 4 illustrates a simulation result indicating the amount of vibration of the multilayer capacitor built-in substrate in each of the examples and the comparative examples.

As understood from FIG. 4, the amount of vibration was about 44 nm in Comparative Example 1 in which no resin layer is provided on a principal surface of the circuit board, but the amount of vibration was larger than that of Comparative Example 1 in Comparative Example 2 in which the first epoxy resin layer having the smaller Young's modulus is provided on a principal surface of the circuit board, and Comparative Example 3 in which the first epoxy resin layer having the smaller Young's modulus is provided on the upper surface and side surface of the multilayer ceramic capacitor. As the reason, it is presumed that vibration attributable to distortion of the multilayer ceramic capacitor propagated to the first epoxy resin layer having the smaller Young's modulus in addition to the insulating layer having the larger Young's modulus, and thus the vibration was larger than with the configuration in which no resin layer is provided.

In Comparative Example 4 in which the second epoxy resin layer having the larger Young's modulus is provided on a principal surface of the circuit board to embed the multilayer ceramic capacitor, the amount of vibration was smaller than that in Comparative Example 1. As the reason, it is presumed that since the multilayer ceramic capacitor was completely covered by the second epoxy resin layer, vibration attributable to distortion of the multilayer ceramic capacitor propagated not only to the insulating layer of the circuit board but also to the second epoxy resin layer so that vibration propagating to both sides canceled each other.

In Examples 1 and 2, the first epoxy resin layer having the smaller Young's modulus was provided between the second epoxy resin layer having the larger Young's modulus and the insulating layer of the circuit board so that the amount of vibration was smaller than that in Comparative Example 4 unlike Comparative Examples 2 and 3. As the reason, it is presumed that vibration was further reduced by the first epoxy resin layer having the smaller Young's modulus.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer capacitor built-in substrate comprising:
a circuit board;
a multilayer capacitor mounted on one principal surface of the circuit board;
a first resin layer provided on the one principal surface of the circuit board; and
a second resin layer provided on the first resin layer and embedding the multilayer capacitor; wherein
a Young's modulus of the first resin layer is smaller than a Young's modulus of the second resin layer.

2. The multilayer capacitor built-in substrate according to claim 1, wherein the first resin layer is also provided on an upper surface and a side surface of the multilayer capacitor to cover the multilayer capacitor.

3. The multilayer capacitor built-in substrate according to claim 1, wherein E1/E2<0.5 is satisfied, where the Young's modulus of the first resin layer is represented by E1 and the Young's modulus of the second resin layer is represented by E2.

4. The multilayer capacitor built-in substrate according to claim 1, wherein a thickness of the first resin layer is smaller than a thickness of the multilayer capacitor.

5. The multilayer capacitor built-in substrate according to claim 1, wherein the first resin layer and the second resin layer each include epoxy resin.

6. The multilayer capacitor built-in substrate according to claim 1, wherein the multilayer ceramic capacitor has a rectangular or substantially rectangular parallelepiped shape.

7. The multilayer capacitor built-in substrate according to claim 1, wherein the multilayer ceramic capacitor includes an element body and external electrodes respectively covering an end portion of an element body.

8. The multilayer capacitor built-in substrate according to claim 7, wherein each of the external electrodes are defined by a multilayer film including a sintered metal layer and a plating layer.

9. The multilayer capacitor built-in substrate according to claim 8, the sintered metal layer is made of a backing paste including at least one of Cu, Ni, Ag, Pd, an Ag—Pd alloy or Au.

10. The multilayer capacitor built-in substrate according to claim 8, wherein the plating layer includes a Ni plating layer and an Sn plating layer covering the Ni plating layer.

11. The multilayer capacitor built-in substrate according to claim 1, wherein
the circuit board includes a plurality of insulating layers and lands provided on a surface of one of the plurality of insulating layers; and
the multilayer ceramic capacitor is mounted on the lands.

12. The multilayer capacitor built-in substrate according to claim 11, wherein each of the plurality of insulating layers includes glass epoxy resin impregnated with epoxy resin in glass woven fabric.

13. The multilayer capacitor built-in substrate according to claim 11, wherein a Young's modulus of each of the plurality of insulating layers is in a range of about 15 GPa to about 30 GPa.

14. The multilayer capacitor built-in substrate according to claim 11, wherein a thickness of each of the plurality of insulating layers is in a range of about 15 μm to about 1000 μm.

15. The multilayer capacitor built-in substrate according to claim 11, wherein the lands are made of copper foil.

16. The multilayer capacitor built-in substrate according to claim 1, wherein the Young's modulus of the first resin layer is about 0.01 GPa or larger, and the Young's modulus of the second resin layer is about 10 GPa or smaller.

17. The multilayer capacitor built-in substrate according to claim 1, wherein the Young's modulus of the first resin layer is about 0.05 GPa or larger, and the Young's modulus of the second resin layer is about 3 GPa or smaller.

18. The multilayer capacitor built-in substrate according to claim 1, wherein a thickness of the first resin layer is about 300 μm or smaller.

19. The multilayer capacitor built-in substrate according to claim 1, wherein a thickness of the first resin layer is about 200 μm or smaller.

20. The multilayer capacitor built-in substrate according to claim 19, wherein a thickness of the first resin layer is about 50 μm or larger.
